(19) United States
(12) Patent Application Publication
(10) Pub. No.: US 2007/0264843 A1
(43) Pub. Date: Nov. 15, 2007

(54) Formation and applications of nitrogen-free silicon carbide in semiconductor manufacturing

(75) Inventors: Lih-Ping Li, Hsinchu (TW); Yung-Cheng Lu, Taipei (TW); Tien-I. Bao, Hsin-Chu (TW); Syun-Ming Jang, Hsin-Chu (TW); Ying-Tsung Chen, Chiayi City (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 11/430,623

(22) Filed: May 9, 2006

(51) Int. Cl. H01L 21/31

(52) U.S. Cl. 438/771; 257/E21.27

(57) ABSTRACT

A method for manufacturing an integrated circuit is provided. In one example, the method includes forming a substantially nitrogen-free silicon carbide layer over a substrate using a methyl silicate gas.

### BACKGROUND

Traditionally, an etch stop layer may be formed using tetra-methyl silicate (4MS) gas or tri-methyl silicate (3MS) gas and adding NH₃. Deep-ultraviolet (DUV) photoresists, such as those that may be used for patterning semiconductor wafers, use a chemical amplification process that is dependent on photogenerated acids produced during an exposure step. However, the etch stop layer thus formed contains nitrogen, may form photoresist scum, may poison (or neutralize) the photoresist, and may cause photoresist failure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a sectional view of one embodiment of an exemplary semiconductor structure with use of a substantially nitrogen-free silicon carbide material formed in accordance with the present disclosure.

FIG. 2 is a flowchart of one embodiment of a method for forming a substantially nitrogen-free silicon carbide material.

### WRITTEN DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

In traditional etch stop layers, tri-methyl silicate (3MS) or tetra-methyl silicate (4MS) are usually used as precursors by adding ammonia (NH₃) to form silicon oxycarbide (SiOC). Such SiOC etch stop layers may have relatively good etching selectivity and resist copper (Cu) diffusion, but photoresist (PR) poisoning has been found with the presence of nitrogen in SiOC.

Further, in deep submicron or nanometer integrated circuits, porous low-k materials may be used due to their very low dielectric constants. However, porous low-k materials may be damaged by chemical mechanical polishing (CMP) processes. Traditional SiOC layers may be used as a cap layer to avoid CMP processing damage, but photoresist scum may be formed because of the presence of nitrogen in the traditional SiOC material.

In one embodiment, in contrast to the traditional method of forming SiOC, a compound material formed in accordance with the present disclosure includes carbon and silicon, and may include oxygen in some embodiments (hereafter referred to as nitrogen-free SiC for purposes of convenience, whether containing oxygen or not). The nitrogen-free SiC may additionally include hydrogen, and may be formed using methyl silicate gas and an oxygen-containing precursor. When containing oxygen, this compound material has a generic formula of SiₐC_{b}H_{c}O_{d}. The methyl silicate gas may be tri-methyl silicate (3MS) or tetra-methyl silicate (4MS). The methyl silicate gas may alternatively include silane or another methyl silicate gas. The oxygen-containing precursor may be carbon dioxide (CO₂) or may be CO, O₂, O₃, tetraethylorthosilane (TEOS), and combinations thereof. The nitrogen-free SiC may be formed by a process such as chemical vapor deposition (CVD) or plasma enhanced CVD (PECVD). In the present example, the formation of the nitrogen-free SiC (with oxygen) is accomplished using a process having the following conditions:
a 4MS (or 3MS) gas flow from about 10 to 500 sccm;
an oxygen-containing gas flow from about 50 to 5000 sccm;
a total pressure from about 1.5 to 5.0 torr; and
a temperature from about 200 to 450° C.

The processing chamber may also include radio frequency (RF) electric power of about two watt/cm². The process may also include introducing a carrier gas, which is usually an inert gas such as nitrogen (N₂) gas. The carrier gas may alternatively be helium or argon. The carrier gas flow may range from about 500 to 3000 sccm and preferably from about 500 to 1500 sccm.

The nitrogen-free SiC compound may be used as an etch stop layer (ESL) to provide etching selectivity, a barrier to provide resistance to copper diffusion, a capping layer to protect an underlying layer (e.g., a porous low-k dielectric layer) from damage from CMP or similar processes, or an anti-reflective layer to reduce reflection in later processing steps. It is understood that all of these functions can be achieved alternatively or collectively. For example, an etch stop layer may also function as a barrier to provide a resistance to copper diffusion. In another example, a capping layer may also function as an anti-reflective layer to reduce reflection during a photolithography patterning process.

The nitrogen-free SiC formed in accordance with the present disclosure may have an oxygen content tuned for various applications by varying the processing conditions, including the chemical flow rates, pressure, temperature, and RF electric power. In one embodiment, the oxygen content may be tuned to about 15% or less for optimized resistance to copper diffusion. In one experiment, bias-thermal stress (BTS) test and secondary ion mass spectrometry (SIMS) measurement data have shown that there is little or no copper diffusion even if the oxygen content is upwards of about 15%. In another embodiment, the oxygen content may be tuned to a range from about 5% to 12% to provide etching selectivity when used as an etch stop layer. For example, the etch selectivity may be tuned to a range from about 2 to 10. Furthermore, the nitrogen-free SiC is substantially nitrogen-free and can be used with a photoresist, such as a chemical amplification photoresist, with minimized or eliminated photoresist poisoning and/or scum issues. It is understood that the term “substantially nitrogen-free” indicates that the SiC material is totally free of nitrogen or contains only trace amounts of nitrogen that do not affect the material's desired uses.

In another embodiment, the oxygen content and/or other component contents of the nitrogen-free SiC may be predetermined such that the refractive index of the nitrogen-free SiC is tuned to substantially reduce reflection when used as an anti-reflective layer during a photolithography patterning process. The dielectric constant of the nitrogen-free SiC is tunable and may range from about 1.5 to 3.5. Other characteristics, such as adhesion to low-k dielectric material, may also be improved by selecting appropriate processing conditions, such as a high processing pressure.

In a further embodiment, the nitrogen-free SiC may be formed without the use of an oxygen-containing gas and thus is substantially oxygen-free. Other than the absence of the oxygen-containing gas during the formation of the nitrogen-free SiC, the nitrogen-free SiC may be substantially similar to that described in previous embodiments in terms of formation and composition. For example, formation conditions including total pressure, temperature, and RF electric power may be similar to those in the embodiments having presence of the oxygen-containing gas. The compound material thus formed has a generic formula of SiₐC_{b}H_{c}. As stated previously, both compound materials (SiₐC_{b}H_{c}O_{d} and Si₈C_{b}H_{c}) are collectively referred to as nitrogen-free SiC in the present specification.

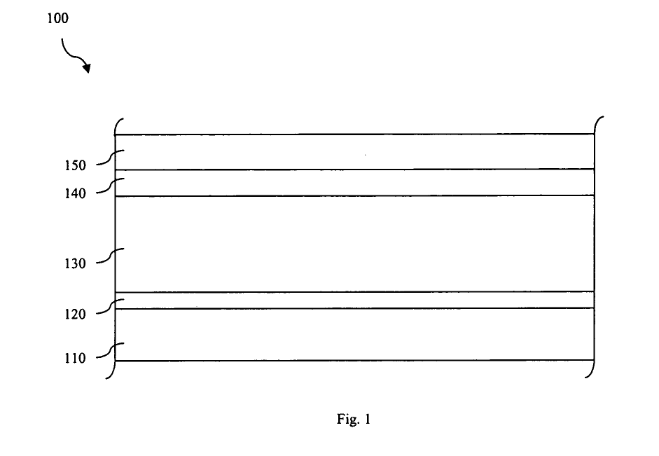

Referring to FIG. 1, illustrated is a sectional view of one embodiment of a semiconductor structure 100 constructed according to aspects of the present disclosure. The semiconductor device 100 includes a substrate 110. In the disclosed embodiment, the substrate 110 includes a silicon semiconductor wafer including crystalline silicon. The substrate 110 may alternatively include polycrystalline silicon, amorphous silicon, or any other suitable semiconductor material such as elementary semiconductor, compound semiconductor, and/or alloy semiconductor. The substrate 110 may further includes a plurality of doped regions formed therein (not shown). The substrate 110 may include a plurality of patterned conductive (such as copper or copper alloy) and dielectric structures (such as low-k material) formed thereon (not shown). The substrate 110 may also include non-semiconductor material such as glass used to form thin-film-transistor liquid-crystal display (TFT-LCD) devices.

An etch stop layer 120 may be formed on the substrate 110. The etch stop layer 120 is one of the nitrogen-free SiC materials (SiₐC_{b}H_{c}O_{d} and SiₐC_{b}H_{c}) described in the above embodiments in terms of composition and formation. In the present example, the etch stop layer 120 may have a thickness ranging from about 350 to 600 Å, but it is understood that other thicknesses may be used. The composition may be tuned to provide optimized etching selectivity and/or resistance to copper diffusion if a copper structure is present. For example, the etch stop layer 120 may have an etching selectivity over an underlying low-k material or copper of from about 2 to 10. The etch stop layer 120 may also be tuned to function as a capping layer to protect an underlying low-k material and/or an anti-reflective layer used for a subsequent photolithography patterning process.

A low-k (low dielectric constant) material layer 130 may be formed over the etch stop layer 120. The low-k material layer 130 may have a dielectric constant less than 3.9, the dielectric constant of thermal silicon dioxide. For example, the low-k material 130 used may have a dielectric constant ranging from about 3.8 to about 2 or even less. The low-k material 130 may include fluorinated silica glass (FSG), carbon doped silicon oxide, combinations thereof, and/or other low-k material. Other optional low-k materials may include Black Diamond® (Applied Materials of Santa Clara, Calif.), Xerogel, Aerogel, amorphous fluorinated carbon, Parylene, BCB (bis-benzocyclobutenes), SiLK (Dow Chemical, Midland, Mich.), polyimide, and/or other materials. The low-k material may be formed by CVD, ALD, PVD, spin-on coating (spin-on polymer or SOP), and/or other suitable processes. An interconnect isolation material may be formed by using dielectric material such as silicon oxide in combination with the low-k material and may adopt multilayer structure. The low-k material, while being used for interconnect isolation, may reduce RC delay and enhance device speed.

A capping layer 140 may be formed on the low-k material layer 130. The capping layer 140 may be one of the nitrogen-free SiC materials (SiₐC_{b}H_{c}O_{d} and SiₐC_{b}H_{c}) described in the above embodiments in terms of composition and formation. The capping layer 140 may have a thickness ranging from about 100 to 500 Å. The composition may be tuned to provide a sealing effect and mechanical strength to protect the low-k material (usually a porous material) from damage, especially during a subsequent CMP process. Additionally, an anti-reflective layer may be formed on the capping layer after CMP processing and may use a similar methyl silicate gas. Alternatively, the capping layer 140 may also be tuned to also function as an anti-reflective layer.

A photoresist layer 150 may be formed on the capping layer 140 and be followed by further photolithography processing, which may include soft baking, exposing, post exposure baking, developing, hard baking, etching, and/or photoresist stripping. The photoresist layer 150 may be formed by a technique such as a spin-on process. The photoresist layer 150 may be chemical amplification photoresist material that includes a photoacid generator (PAG). As is known, photons decompose PAG during an exposure process and form acid. More acid may be produced due to later chemical amplification, especially during a post exposure baking process. Since the underlying capping layer 140 or, alternatively, the anti-reflective layer formed in accordance with the present disclosure is nitrogen-free, photoresist poisoning and scum issues are substantially minimized or eliminated.

Additional processing steps may be performed, such as processing steps used in a dual damascene process. For example, the low-k material 130 may be etched to form trenches and/or vias that are then filled with copper alloy for conductive interconnects. In another example, the capping layer 140 may be formed after trenches and/or vias are formed in the low-k material layer 130. It is understood that the semiconductor structure 100 is only an example to illustrate the use of the nitrogen-free SiC materials that may be formed in accordance with the present disclosure and incorporated into a semiconductor manufacturing process and semiconductor integrated circuits formed by such a process. The described method may be modified and extended. For example, the nitrogen-free SiC material may be used to form an etch stop layer, a capping layer, an anti-reflective layer, or any other layer where such a material may be desired, and may be used to form one or more of the layers in various configurations, combinations, and/or sequences.

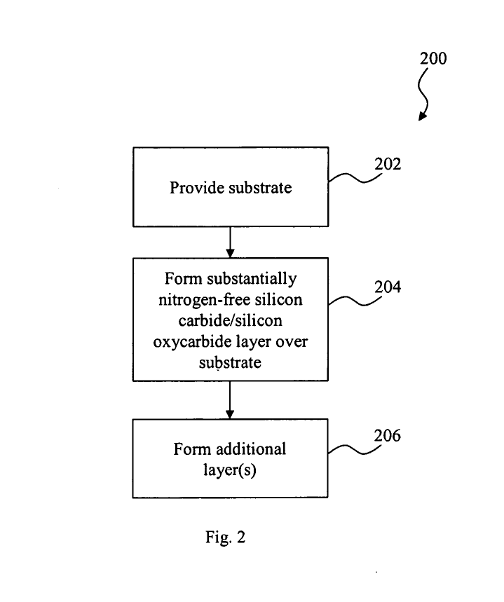

Referring to FIG. 2, in one embodiment, the present disclosure provides a method 200 for forming a nitrogen-free SiC layer incorporated into an integrated circuit manufacturing process. The method includes providing a substrate in step 202; forming substantially nitrogen-free silicon carbide or silicon oxycarbide layer (SiC layer) over the substrate in step 204; and forming one or more additional layers (e.g., a photoresist layer) over the nitrogen-free SiC layer in step 206. The forming of the nitrogen-free SiC layer includes using a methyl silicate gas and an oxygen-containing precursor.

In the present example, the methyl silicate gas may be selected from tetra-methyl silicate (4MS) gas, tri-methyl silicate (3MS) gas, and combinations thereof. The oxygen-containing precursor may be selected from CO, CO₂, O₂, O₃, tetraethylorthosilane (TEOS), and combinations thereof. The nitrogen-free SiC layer may include an oxygen content of less than about 15% in weight, such as an oxygen content ranging between about 5% and 12% in weight. The forming of the nitrogen-free SiC layer may include the use of a methyl silicate gas flow of from about 10 to 500 sccm, and an oxygen-containing gas flow of from about 50 to 5000 sccm. The forming of the nitrogen-free SiC layer may include a carrier gas selected from nitrogen, helium, argon, and combinations thereof. The forming of the nitrogen-free SiC layer may include a flow of the carrier gas ranging from about 500 to 1500 sccm. The forming of the nitrogen-free SiC layer may include a total pressure of from about 1.5 to 5.0 torr, and a temperature of from about 200 to 450° C. The nitrogen-free SiC layer may have a dielectric constant of from about 1.5 to 3.5. The nitrogen-free SiC layer may serve as an etch stop layer, a capping layer, an anti-reflective layer, a barrier layer, or combinations thereof. The forming of the nitrogen-free SiC layer may include tuning composition contents of the silicon oxycarbide layer to enhance anti-reflection. The nitrogen-free SiC layer may have an etch selectivity of from about 2 to 10. The nitrogen-free SiC layer may further include hydrogen.

In another embodiment, the present disclosure provides a method used in semiconductor manufacturing. The method includes providing a substrate and forming a dielectric layer over the substrate. Forming the dielectric layer includes providing silicon, carbon, and hydrogen over the substrate in a substantially nitrogen free environment and uses a methyl silicate gas including at least one of a tetra-methyl silicate (4MS) gas and a tri-methyl silicate (3MS) gas.

In the present method, the forming of the dielectric layer may include the use of a methyl silicate gas flow of from about 10 to 500 sccm; a total pressure of from about 1.5 to 5.0 torr; a temperature of from about 200 to 450° C.; and a radio frequency electric power about two watt/cm². The forming of the dielectric layer may include introducing an oxygen-containing gas, such as CO, CO₂, O₂, O₃, tetraethylorthosilane (TEOS), and combinations thereof. The forming of the dielectric layer may include introducing a carrier gas such as nitrogen, helium, argon, and combinations thereof.

In still another embodiment, a method includes providing a substrate having an integrated circuit pattern formed thereon; forming an etch stop layer over the substrate; forming a low-k dielectric layer over the etch stop layer; forming a capping layer over the low-k dielectric layer; and forming a photoresist layer over the dielectric layer. At least one of the etch stop layer and the capping layer silicon are formed from a compound of carbon, hydrogen, oxygen, and silicon, substantially nitrogen-free, using a methyl silicate gas. The forming of the at least one of the etch stop layer and the capping layer may include the use of methyl silicate gas, such as tetra-methyl silicate (4MS) gas, tri-methyl silicate (3MS), silane, and combinations thereof. The forming of at least one of the etch stop layer and the capping layer may include introducing an oxygen-containing gas, such as CO, CO₂, O₂, O₃, tetraethylorthosilane (TEOS), and combinations thereof.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method comprising:
providing a substrate;
forming a substantially nitrogen-free silicon oxycarbide layer over the substrate using a methyl silicate gas and an oxygen-containing precursor; and
forming a photoresist layer over the silicon oxycarbide layer.

2. The method of claim 1, wherein the methyl silicate gas is selected from the group consisting of tetra-methyl silicate (4MS) gas, tri-methyl silicate (3MS) gas, and combinations thereof.

3. The method of claim 1, wherein the oxygen-containing precursor is selected from the group consisting of CO, CO₂, O₂, O₃, tetraethylorthosilane (TEOS), and combinations thereof.

4. The method of claim 1, wherein the silicon oxycarbide layer includes an oxygen content of less than about 25% in weight.

5. The method of claim 1, wherein the silicon oxycarbide layer includes an oxygen content ranging between about 5% and 12% in weight.

6. The method of claim 1, wherein the forming of the silicon oxycarbide layer includes providing a methyl silicate gas flow of from about 10 to 500 sccm, and an oxygen-containing precursor gas flow of from about 50 to 5000 sccm.

7. The method of claim 1, wherein the forming of the silicon oxycarbide layer includes providing a carrier gas selected from the group consisting of nitrogen, helium, argon, and combinations thereof.

8. The method of claim 7, wherein the forming of the silicon oxycarbide layer comprises providing a flow of the carrier gas ranging from about 500 to 1500 sccm.

9. The method of claim 1, wherein the forming of the silicon oxycarbide layer comprises a total chamber pressure of from about 1.5 to 5.0 torr, and a temperature of from about 200 to 450° C.

10. The method of claim 1, wherein the silicon oxycarbide layer is formed to have a dielectric constant of from about 1.5 to 3.5.

11. The method of claim 1, wherein the silicon oxycarbide layer is formed as an etch stop layer.

12. The method of claim 1, wherein the silicon oxycarbide layer serves as one of the group consisting of an etch stop layer, a capping layer, an anti-reflective layer, a barrier layer, and combinations thereof.

13. The method of claim 1, wherein the forming of the silicon oxycarbide layer further comprises tuning at least one material used to form the silicon oxycarbide layer to enhance anti-reflection.

14. The method of claim 1, wherein the silicon oxycarbide layer has an etch selectivity of from about 2 to 10.

15. The method of claim 1, wherein the silicon oxycarbide layer further comprises hydrogen.

16. A method, comprising:
providing a substrate; and
forming a dielectric layer over the substrate, wherein the forming includes providing silicon, carbon, and hydrogen over the substrate in a substantially nitrogen free environment and uses a methyl silicate gas including at least one of a tetra-methyl silicate (4MS) gas and a tri-methyl silicate (3MS) gas.

17. The method of claim 16, wherein the forming of the dielectric layer comprises:
a methyl silicate gas flow of from about 10 to 500 sccm;
a total chamber pressure of from about 1.5 to 5.0 torr;
a temperature of from about 200 to 450° C.; and
a radio frequency electric power of about 2 watt/cm².

18. The method of claim 16, wherein the forming of the dielectric layer comprises introducing a carrier gas selected from the group consisting of nitrogen, helium, argon, and combinations thereof.

19. The method of claim 16, wherein the forming of the dielectric layer further includes introducing an oxygen-containing gas.

20. The method of claim 19, wherein the oxygen-containing gas is selected from the group consisting of CO, CO₂, O₂, O₃, tetraethylorthosilane (TEOS), and combinations thereof.

21. A method, comprising:
providing a substrate having an integrated circuit pattern formed thereon;
forming an etch stop layer over the substrate;
forming a low-k dielectric layer over the etch stop layer;
forming a capping layer over the low-k dielectric layer; and
forming a photoresist layer over the dielectric layer, wherein at least one of the etch stop layer and the capping layer is a compound of carbon, hydrogen, oxygen, and silicon, substantially nitrogen-free, and is formed using a methyl silicate gas.

22. The method of claim 21, wherein the methyl silicate gas is selected from the group consisting of tetra-methyl silicate (4MS) gas, tri-methyl silicate (3MS), silane, and combinations thereof.

23. The method of claim 21, wherein the forming of at least one of the etch stop layer and the capping layer comprises introducing an oxygen-containing gas selected from the group consisting of CO, CO₂, O₂, O₃, tetraethylorthosilane (TEOS), and combinations thereof.

24. A method comprising:
providing a substrate; and
forming a substantially nitrogen-free silicon carbide layer over the substrate using a methyl silicate gas.

25. The method of claim 24 further comprising providing an oxygen-containing precursor when forming the substantially nitrogen-free silicon carbide layer, wherein the silicon carbide layer formed thereby includes an oxygen content of less than about 25% in weight.

26. The method of claim 24 further comprising providing hydrogen when forming the substantially nitrogen-free silicon carbide layer.
